(19) United States
(12) Patent Application Publication
(10) Pub. No.: US 2023/0420973 A1
(43) Pub. Date: Dec. 28, 2023

(54) ELECTRONIC DEVICE METHOD FOR CONTROLLING CHARGING CURRENT FOR MULTIPLE BATTERIES BASED ON SENSING RESISTORS

(71) Applicant: SAMSUNG ELECTRONICS CO., LTD., Suwon-si (KR)

(72) Inventors: Jinyoung JANG, Suwon-si (KR); Jimyung HA, Suwon-si (KR); Eunsoo PARK, Suwon-si (KR); Yonggil HAN, Suwon-si (KR)

(21) Appl. No.: 18/310,111

(22) Filed: May 1, 2023

Related U.S. Application Data
(63) Continuation of application No. PCT/KR2023/004740, filed on Apr. 7, 2023.

(30) Foreign Application Priority Data
Jun. 24, 2022 (KR) 10-2022-0077867
Aug. 16, 2022 (KR) 10-2022-0102234

(51) Int. Cl. H02J 7/00; G06F 1/28

(52) U.S. Cl. CPC H02J 7/00716; G06F 1/28; H02J 7/00304; H02J 7/0013

(57) ABSTRACT

An electronic device includes: at least one processor, a first battery, a second battery, a first sensing integrated circuit (IC) configured to identify a measurement value of a total charging current for charging the first battery and the second battery through a first sensing resistor connected to the first battery and the second battery, and a second sensing IC configured to identify a second charging current value for the second battery through a second sensing resistor connected to the second battery. The at least one processor may be configured to set the total charging current to a first value. The at least one processor may be configured to set the total charging current to a second value, the second value being less than the first value, based on identifying a first charging current value greater than a first reference value or the second charging current value greater than a second reference value.

### CROSS-REFERENCE TO RELATED APPLICATION(S)

This application is a continuation of International Application No. PCT/KR2023/004740, designating the United States, filed on Apr. 7, 2023, in the Korean Intellectual Property Receiving Office and claiming priority to Korean Patent Application No. 10-2022-0077867, filed on Jun. 24, 2022, in the Korean Intellectual Property Office, and to Korean Patent Application No. 10-2022-0102234, filed on Aug. 16, 2022, in the Korean Intellectual Property Office, the disclosures of all of which are incorporated by reference herein in their entireties.

### BACKGROUND

### Technical Field

The disclosure relates to an electronic device and a method for controlling charging current for multiple batteries based on a sensing resistance.

### Description of Related Art

An electronic device may have a plurality of batteries. The electronic device may need to detect an intensity of current flowing through each battery in order to prevent overcurrent. The electronic device may control a charging current based on the detected strength of the current.

An electronic device having a plurality of batteries may need to detect the intensity of current flowing through each battery. When the current is measured based on an active device, an error may be caused in the measurements of current value. Due to such an error, the electronic device may not be able to accurately determine the level of charging (e.g., fuel gauge). As such, the battery may rapidly discharge.

### SUMMARY

The technical problems to be addressed in this disclosure are not limited to those described above, and other technical problems not mentioned herein will be clearly understood by those having ordinary knowledge in the technical field to which the present disclosure belongs, from the following description.

According to an example embodiment, an electronic device includes: at least one processor, a first battery, a second battery, a first sensing integrated circuit (IC) configured to identify a measurement value of a total charging current for charging the first battery and the second battery through a first sensing resistor electrically connected to the first battery and the second battery, and a second sensing IC configured to identify a second charging current value for the second battery through a second sensing resistor electrically connected to the second battery. The at least one processor is configured to: set a total charging current for charging the first battery and the second battery to a first value; and set the total charging current to a second value, the second value being less than the first value, based on identifying a first charging current value greater than a first reference value or the second charging current value greater than a second reference value; wherein first charging current value is identified based on a measurement value of the total charging current and the second charging current value.

According to an example embodiment, a method performed by an electronic device is provided. The method comprises: setting a total charging current for charging a first battery and a second battery to a first value; identifying a measurement of the total charging current through a first sensing resistor electrically connected the first battery and the second battery; identifying a second charging current value for the second battery through the second sensing resistor electrically connected the second battery; and setting the total charging current to a second value less than the first value based on identifying a first charging current value greater than a first reference value or the second charging current value greater than a second reference value; wherein first charging current value is identified based on the measurement value of the total charging current and the second charging current value.

According to an example embodiment, an electronic device comprises: a first battery, a second battery, an interface power management integrated circuit (IF PMIC) configured to charge the first battery and the second battery, a direct current integrated circuit (DC IC), a first sensing resistor connected to the IF PMIC, a second sensing resistor connected to the DC IC, and at least one processor configured to control the IF PMIC and the DC IC; wherein first sensing resistor is disposed between the IF PMIC and the first battery, and the second sensing resistor is disposed between the first sensing resistor and the second battery.

Various example embodiments of the disclosure can detect the intensity of current flowing through a respective battery using a passive element instead of an active element. Unlike the case of using such an active device for current measurement, embodiments of the disclosure can prevent and/or reduce rapid discharge of a battery. Further, embodiments of the disclosure can increase accuracy of measuring current flowing through a battery.

The effects that can be obtained from the disclosure are not limited to those described above, and any other effects not mentioned herein will be clearly understood by those having ordinary knowledge in the technical field to which the disclosure belongs, from the following description.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2A is a block diagram illustrating an example circuit layout of an electronic device according to various embodiments;

FIG. 2B is a block diagram illustrating an example circuit layout of an electronic device according to various embodiments;

FIG. 2C is a block diagram illustrating an example circuit layout of an electronic device according to various embodiments;

FIG. 3 is a flowchart illustrating an example operation of an electronic device for preventing and/or reducing overcurrent according to various embodiments;

FIG. 4 is a flowchart illustrating an example operation of an electronic device for stabilizing a first charging current value and a second charging current value according to various embodiments;

FIG. 5 is a flowchart illustrating an example operation of an electronic device for indicating an abnormal state of a path between a battery and a resistor according to various embodiments;

FIG. 6 is a diagram illustrating an example electronic device according to various embodiments;

FIG. 7 is a perspective view illustrating an example of an unfolded state of an electronic device according to various embodiments;

FIG. 8 is a perspective view illustrating an example of a folded state of an electronic device according to various embodiments;

FIG. 9A is a graph illustrating performance of charging current control of an electronic device using a limiter according to various embodiments; and

FIG. 9B is a graph illustrating performance of charging current control of an electronic device using a passive element according to various embodiments.

### DETAILED DESCRIPTION

The terms used in the disclosure are used to describe various example embodiments, and are not intended to limit the scope of the disclosure. Singular expressions may include plural expressions unless the context clearly indicates otherwise. The terms used herein, including technical or scientific terms, may have the same meaning as commonly understood by one having ordinary skill in the technical field described in this disclosure. Among those terms used in the disclosure, the terms defined in general dictionaries may be interpreted as having the same or similar meanings as those in the context of the related art, and unless explicitly defined in the present disclosure, may not interpreted as ideal or excessively formal meanings. In some cases, even terms defined in the present disclosure shall not be interpreted to exclude embodiments of the disclosure.

In various embodiments of the disclosure described below, a hardware-based access method is described as an example. However, since the various example embodiments of the disclosure include the technology using both the hardware and the software, various example embodiments of the disclosure shall not exclude any software-based access methods.

As used herein, the terms referring to parts of electronic devices (e.g., module, device, IC (integrated chip), circuit, processor, chip, component, device, etc.), the terms referring to active devices (e.g., IF PMIC (interface power management IC), DC (direct current) IC, limiter IC, etc.), the terms referring to circuits (e.g., PCB (printed circuit board), FPCB (flexible printed circuit board), signal line, data line, etc.) are illustrated for convenience of explanation. The disclosure is not limited to the terms described below, and other terms having equivalent technical meanings may be used. Further, as used herein, the terms such as e.g., ‘˜ module’, ‘˜ unit’, ‘— part’, ‘˜ section’, ‘˜ body’, etc. may refer to at least one shape of structure or a unit to process a function.

Furthermore, in the disclosure, an expression such as e.g., ‘more than’ or ‘less than’ may be used to determine whether a specific condition is satisfied or fulfilled, but it is merely a description for expressing a certain example, and it shall not exclude a description of ‘equal to or more than’ or ‘equal to or less than’ condition. Therefore, a condition described as ‘equal to or more than’ may be replaced with ‘above (or exceeding)’, a condition described as ‘equal to or less than’ may be replaced with ‘below’, and a condition described as ‘equal to or more than’ and ‘equal to or less than’ may be replaced with ‘above and below’. Further, hereinafter, ‘A’ to ‘B’ refer to at least one of elements from A (inclusive of A) to and B (inclusive of B).

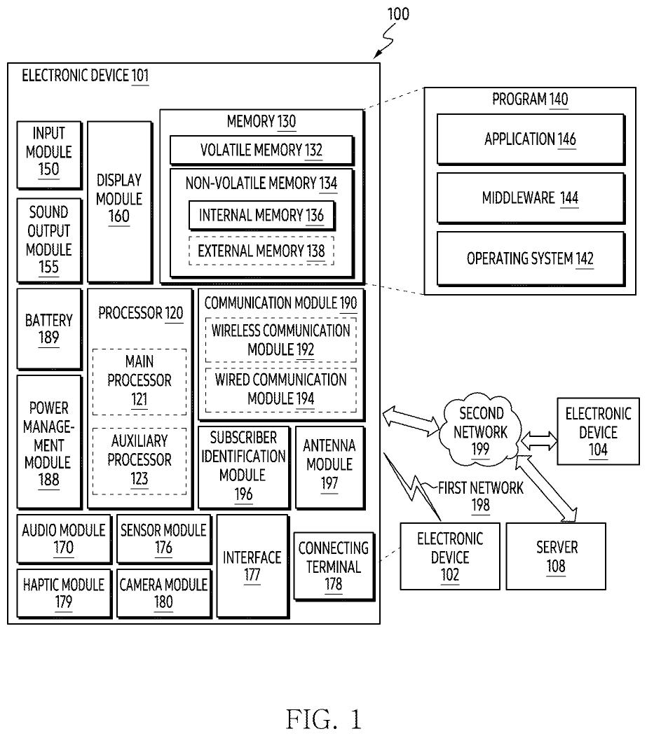

FIG. 1 is a block diagram illustrating an example electronic device in a network environment according to various embodiments.

Referring to FIG. 1, an electronic device 101 in a network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, a memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments of the disclosure, at least one of the components (e.g., the connecting terminal 178) may be omitted from the electronic device 101, or one or more other components may be added in the electronic device 101. In various embodiments of the disclosure, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in a volatile memory 132, process the command or the data stored in the volatile memory 132, and store resulting data in a non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high-definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mm Wave band) to address, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large-scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment of the disclosure, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

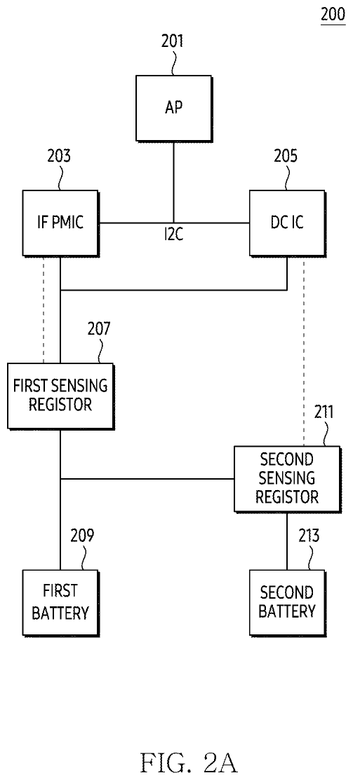

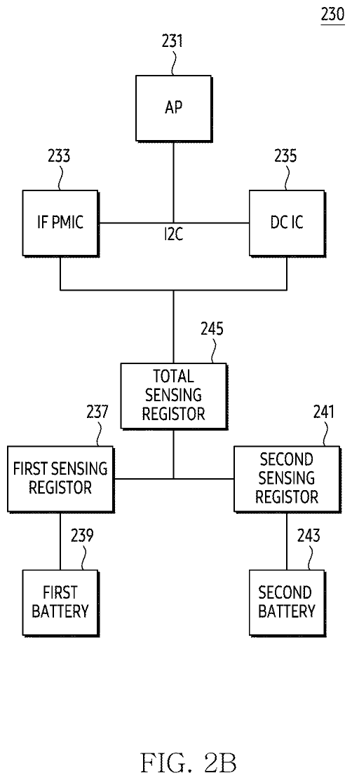

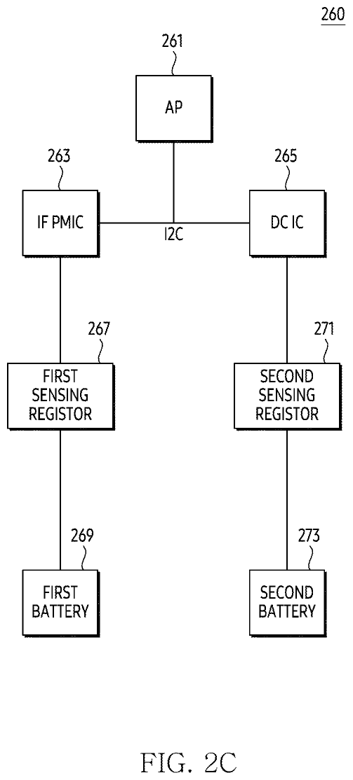

FIG. 2A is a block diagram illustrating an example circuit layout of an electronic device according to various embodiments.

Referring to FIG. 2A, a circuit 200 of an electronic device (e.g., the electronic device 101 of FIG. 1) illustrates an example of an electronic device including a sensing resistor and a battery according to embodiments. An application processor (AP) (e.g., including processing circuitry) 201 may control an interface power management integrated circuit (IF PMIC) 203. The AP 201 may control a direct current integrated circuit (DC IC) 205. Functions of the AP 201 may be described below with operations of a processor (e.g., the processor 120 of FIG. 1). The IF PMIC 203 may be used to charge the electronic device with a first power. The DC IC 205 may be used to charge the electronic device with a second power. A first sensing resistor 207 may be a passive element (e.g., a resistor for measuring current) for measuring a total charging current. A second sensing resistor 211 may be a passive element (e.g., a resistor for measuring current) for measuring a charging current of a second battery 213. The electronic device may include a plurality of batteries (e.g., the battery 189 of FIG. 1). The plurality of batteries may include a first battery 209 and a second battery 213. In FIG. 2A, a solid line connecting each element may, for example, and without limitation, represent an electrical connection of an electrical wire or an FPCB for supplying current. For example, the solid line may refer, for example, to a power line supplying current. A dotted line connecting each element may, for example, and without limitation, represent an electrical connection of an electrical wire or an FPCB for detecting current. For example, the dotted line may refer, for example, to a sensing line. According to an embodiment, a small amount of current may flow through the wire or the FPCB for current sensing. The small amount of current flowing through the current sensing wire or FPCB may not affect the total charging current, the first charging current, and/or the second charging current. Therefore, when measuring the charging current, the at least one processor can identify a measurement value based only on the current flowing through the current supplying wire or FPCB.

The first battery 209 may be located in a first housing area of the electronic device. The second battery 213 may be located in a second housing area of the electronic device. The AP 201 may set the total charging current based on a guaranteed current of each battery of the plurality of batteries. The total charging current may be set to a first value. The term ‘guaranteed current’ may refer, for example, to a recommended current level to maximize and/or improve the lifespan of a battery. For example, the guaranteed current of a battery, which may be a threshold value of current strength in use recommended by a battery manufacturer, may be determined based on at least one of a battery manufacturer, a battery type, and/or a capacity of the battery. The IF PMIC 203 may include a first current sensing IC. The at least one processor measures a value of a total charging current flowing through the first sensing resistor 207, based on the first sensing resistor 207 through the first current measuring IC. For example, the at least one processor can measure a value of the total charging current through a current sensing pin of the first current measuring IC. The DC IC (direct current integrated circuit) 205 may include a second current measuring IC. The at least one processor measures a second charging current value flowing through the second sensing resistor 211, based on the second sensing resistor 211 through the second current measuring IC. For example, the at least one processor measures a value of the second charging current through a current sensing pin of the second current measuring IC. The at least one processor can identify a first charging current value flowing through the first battery 209, based on the measured value of the total charging current and the second charging current value. According to an embodiment, the at least one processor may identify a difference between the measured value of the total charging current and the second charging current as the first charging current value flowing through the first battery 209. The interface power management integrated circuit (IF PMIC) 203 and the direct current integrated circuit (DC IC) 205 may be connected through an inter integrated circuit (I2C).

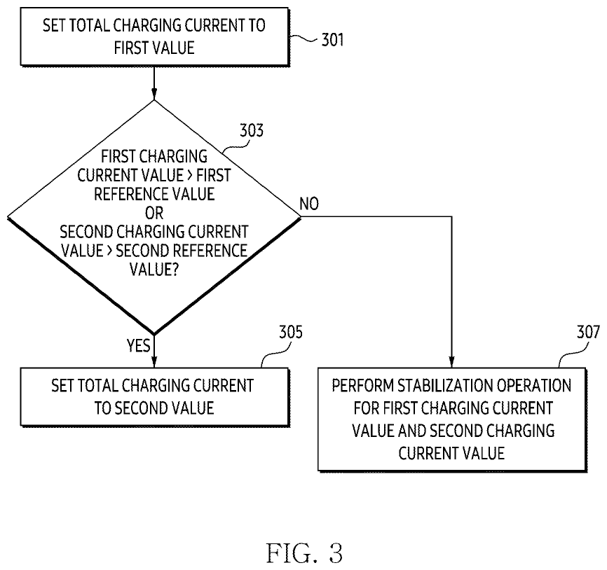

According to an embodiment, the at least one processor may perform an operation to prevent and/or reduce overcurrent. For example, when the first charging current value is equal to or greater than a predetermined (e.g., specified) first reference value corresponding to the guaranteed current of the first battery 209, the at least one processor may perform an operation to prevent and/or reduce occurrence of overcurrent flowing in the first battery 209. For example, when the second charging current value is greater than or equal to a predetermined (e.g., specified) second reference value corresponding to the guaranteed current of the second battery 213, the at least one processor may perform an operation to prevent and/or reduce occurrence of overcurrent flowing in the second battery 213. For example, the at least one processor may lower a setting value of the total charging current to prevent and/or reduce overcurrent from flowing to the first battery 209 or the second battery 213. Detailed description is made below with reference to FIG. 3.

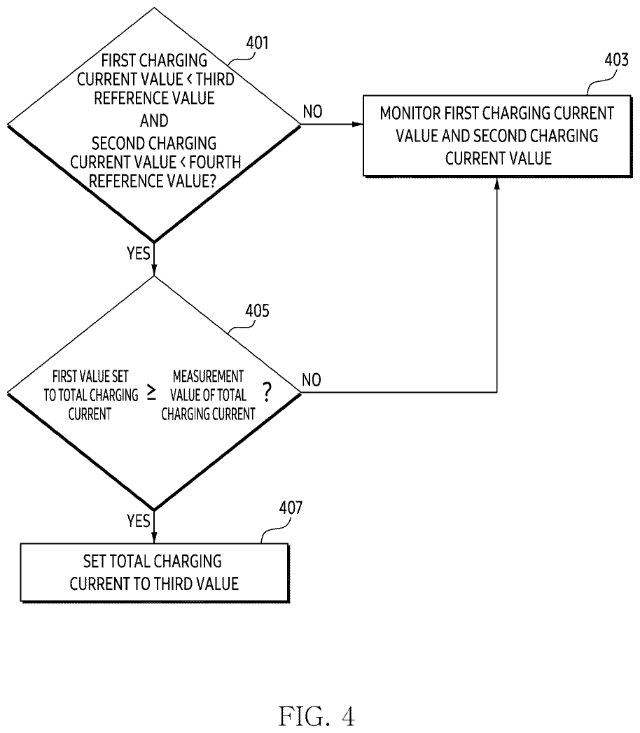

According to an embodiment, the at least one processor may perform an operation for stabilizing the first charging current value and the second charging current value. For example, the at least one processor may perform an operation for stabilizing the first charging current value and the second charging current value in case where the current value flowing through the first battery is lower than a predetermined third reference value, the current value flowing through the second battery is lower than a predetermined fourth reference value, and the measured value of the total charging current is lower than the setting value of the total charging current. For example, the at least one processor may increase the setting value of the total charging current in order to stabilize the first charging current value and the second charging current value. Detailed description thereof will be made with reference to FIG. 4 below.

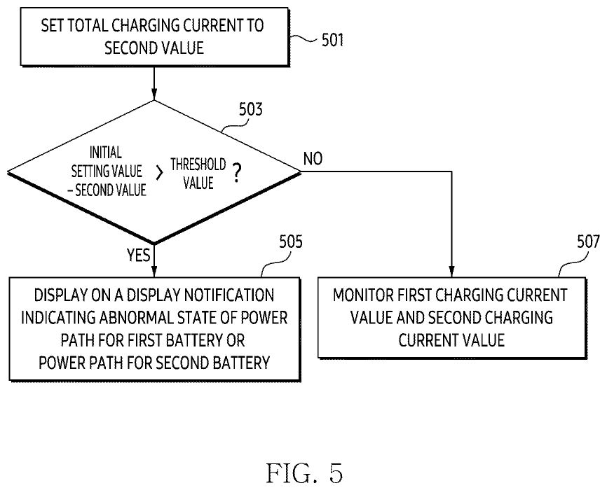

According to an embodiment, when the setting value of the total charging current decreases below a threshold value, the at least one processor may display a notification indicating an abnormal state of a path between the first battery 209 and the first sensing resistor 207 or a path between the second battery 213 and the second sensing resistor 211. A more detailed description of this operation is made below with reference to FIG. 5.

Although FIG. 2A shows that the electronic device 101 has two batteries 209 and 213, embodiments of the present disclosure are not limited thereto. According to an embodiment, the electronic device 101 may further include a third battery and a second sensing resistor, in addition to the first battery 209, the first sensing resistor 207, the second battery 213, and the second sensing resistor 211.

FIG. 2B is a block diagram illustrating an example circuit layout of an electronic device according to various embodiments.

Referring to FIG. 2B, a circuit 230 of an electronic device (e.g., the electronic device 101 of FIG. 1) illustrates an example of an electronic device including a sensing resistor and a battery according to embodiments. An application processor (AP) (e.g., including processing circuitry) 231 may control an interface power management integrated circuit (IF PMIC) 233. The AP 231 may control a direct current integrated circuit (DC IC) 235. The functions of the AP 231 may be described below with reference to operations of a processor (e.g., the processor 120 of FIG. 1). The IF PMIC 233 may be used to charge the electronic device with a first power. The DC IC 235 may be used to charge the electronic device with a second power. A total sensing resistor 245 may be a passive element for measuring the total charging current (e.g., a resistor for measuring current). A first sensing resistor 237 may be a passive element (e.g., a resistor for measuring current) for measuring the charging current of a first battery 239. A second sensing resistor 241 may be a passive element (e.g., a resistor for measuring current) for measuring the charging current of a second battery 243.

The electronic device may include a plurality of batteries (e.g., the battery 189 of FIG. 1). The plurality of batteries may include a first battery 239 and a second battery 243. The first battery 239 may be located in the first housing area of the electronic device. The second battery 243 may be located in the second housing area of the electronic device. The AP 231 may set a total charging current based on a guaranteed current of each battery of the plurality of batteries. The total charging current may be set to a first value. The guaranteed current may refer, for example, to a recommended current level to maximize and/or improve the lifespan of a battery. For example, the guaranteed current of a battery, which may, for example, be a threshold value of current strength recommended by a battery manufacturer, may be determined based on a battery manufacturer, a battery type, and/or a capacity of the battery. The IF PMIC 233 may include a first current sensing IC. The at least one processor may measure a value of a total charging current flowing through the total sensing resistor 245, based on the total sensing resistance 245 through the first current measuring IC. For example, the at least one processor may measure a value of the total charging current through a current sensing pin of the first current measuring IC. The direct current integrated circuit (DC IC) 235 may include a second current measuring IC. The at least one processor may measure a second charging current value flowing through the second sensing resistor 241, based on the second sensing resistor 241 through the second current measuring IC. For example, the at least one processor may measure a value of the second charging current through a current sensing pin of the second current measuring IC. The at least one processor may identify a first charging current value flowing through the first battery 239 based on the measured value of the total charging current and the second charging current value. According to an embodiment, the at least one processor may identify a difference between the measured value of the total charging current and the second charging current, as the first charging current value flowing through the first battery 239. The interface power management integrated circuit (IF PMIC) 233 and the direct current integrated circuit (DC IC) 235 may be connected through an inter integrated circuit (I2C).

According to an embodiment, the at least one processor may perform an operation to prevent and/or reduce overcurrent. For example, in case where the first charging current value is equal to or greater than the first reference value corresponding to the guaranteed current of the first battery 239, the at least one processor may perform an operation to prevent and/or reduce overcurrent from flowing into the first battery 239. For example, in case where the second charging current value is greater than or equal to the second reference value corresponding to the guaranteed current of the second battery 243, the at least one processor may perform an operation to prevent and/or reduce overcurrent from flowing into the second battery 243. For example, the at least one processor may lower a setting value of the total charging current to prevent and/or reduce overcurrent from flowing into the first battery 239 or the second battery 243. The detailed operation thereof is described with reference to FIG. 3 below.

According to an embodiment, the at least one processor may perform an operation for stabilizing the first charging current value and the second charging current value. For example, in case where the current value flowing through the first battery is lower than the third reference value, the current value flowing through the second battery is lower than the fourth reference value, and the measured value of the total charging current is lower than the setting value of the total charging current value, the at least one processor may perform an operation for stabilizing the first charging current value and the second charging current value. For example, the at least one processor may increase the setting value of the total charging current in order to stabilize the first charging current value and the second charging current value. The detailed operation thereof is described below with reference to FIG. 4.

According to an embodiment, when the setting value of the total charging current is lowered below a threshold value, the at least one processor may display a notification indicating an abnormal condition of the path between the first battery 239 and the total sensing resistor 245 or the path between the second battery 243 and the total sensing resistor 245. The detailed operation thereof is described below with reference to FIG. 5.

Although FIG. 2B shows that the electronic device 101 has two batteries 239 and 243, embodiments of the disclosure are not limited thereto. According to an embodiment, the electronic device 101 may further include a third battery and a third sensing resistor, in addition to the first battery 239, the first sensing resistor 237, the second battery 243, and the second sensing resistor 241.

FIG. 2C is a block diagram illustrating an example circuit layout of an electronic device according to various embodiments.

Referring to FIG. 2C, a circuit 260 of an electronic device (e.g., the electronic device 101 of FIG. 1) illustrates an example of an electronic device including a sensing resistor and a battery according to embodiments. An application processor (AP) (e.g., including processing circuitry) 261 may control an interface power management integrated circuit (IF PMIC) 263. The AP 261 may control a direct current integrated circuit (DC IC) 265. The functions of the AP 261 may be described below with operations of a processor (e.g., the processor 120 of FIG. 1). The IF PMIC 263 may be used to charge the electronic device with a first power. The DC IC 265 may be used to charge the electronic device with a second power. The first sensing resistor 267 may be of a passive element (e.g., a resistor for measuring current) for measuring the charging current of the first battery 269. The second sensing resistor 271 may be of a passive element (e.g., a resistor for measuring current) for measuring the charging current of the second battery 273. The total charging current may be obtained as a sum of the first charging current and the second charging current.

The electronic device may include a plurality of batteries (e.g., the battery 189 of FIG. 1). The plurality of batteries may include a first battery 269 and a second battery 273. The first battery 269 may be located in a first housing area of the electronic device. The second battery 273 may be located in a second housing area of the electronic device. The AP 261 may set a total charging current based on a guaranteed current of each battery of the plurality of batteries. The total charging current may be set to a first value. The guaranteed current may refer, for example, to a recommended current level to maximize and/or improve the lifespan of the battery. For example, the guaranteed current of a battery may be a threshold value of current strength recommended by a battery manufacturer, and may be determined based on a battery manufacturer, a type of battery, and/or a capacity of the battery. The IF PMIC 263 may include a first current sensing IC. The at least one processor may measure a value of a first charging current flowing in the first battery 269, based on the first sensing resistor 267 through the first current measuring IC. For example, the at least one processor may measure the value of the first charging current through a current sensing pin of the first current measuring IC. The DC IC 265 may include a second current measurement IC. The at least one processor may measure a second charging current value flowing through the second sensing resistor 271, based on the second sensing resistor 271 through the second current measuring IC. For example, the at least one processor may measure a value of the second charging current through a current sensing pin of the second current measuring IC. The at least one processor may identify the total charging current value based on the measured value of the first charging current and the second charging current value. According to an embodiment, the at least one processor may identify a sum of the measured value of the first charging current and the second charging current as a total charging current value. The IF PMIC 263 and the DC IC 265 may be connected through an inter integrated circuit (I2C).

FIG. 3 is a flowchart illustrating an example operation of an electronic device for preventing and/or reducing overcurrent according to various embodiments. In FIG. 3, the operations of the processor for preventing and/or reducing overcurrent of each battery are described. The operations of the electronic device (e.g., the electronic device 101 of FIG. 1) may be performed by at least one processor of the electronic device (e.g., the processor 120 of FIG. 1, the AP 201 of FIG. 2A, or the processor included in the IF PMIC 203) or by an IC controlled by the at least one processor (e.g., the IF PMIC 203 of FIG. 2A or the DC IC 205 of FIG. 2A).

Referring to FIG. 3, in operation 301, the at least one processor may set the total charging current to a first value. The at least one processor of the electronic device may determine the first value based on the guaranteed current of the first battery (e.g., the first battery 209 of FIG. 2A) and the guaranteed current of the second battery (e.g., the second battery 213 of FIG. 2A).

In operation 303, the at least one processor may identify whether the first charging current value exceeds a first reference value, or the second charging current value exceeds a second reference value. The at least one processor may identify whether the first charging current value exceeds a first reference value. The at least one processor may identify whether the second charging current value exceeds a second reference value. Thus, the first and second charging current values can be identified. According to an embodiment, the first charging current value may be a value obtained by subtracting the second charging current value from the measured value of the total charging current. The measured value of the total charge current may be obtained by the first sensing IC (e.g., the IF PMIC 203 of FIG. 2A). The second charging current value may be obtained by the second sensing IC (e.g., the DC IC 205 of FIG. 2A). The first sensing IC (e.g., IF PMIC 203 of FIG. 2A) may obtain the second charging current value through I2C from the second sensing IC (e.g., DC IC 205 of FIG. 2A). A processor inside the first sensing IC may obtain the first charging current value from the total charging current value and the second charging current value.

According to an embodiment, the at least one processor may detect overcurrent by means of sensing resistors (e.g., the first sensing resistor 207 and/or the second sensing resistor of FIG. 2A), which are not active elements (e.g., limiter IC) but passive elements. When measuring current through such a passive element, the power consumption for current measurement is relatively small and the accuracy of current measurement can be increased. If the current is simply measured using a passive element, it may not be easy for the current flowing in each battery to be determined. Accordingly, the at least one processor may perform an operation for overcurrent determination and charging current control according to embodiments. The at least one processor may identify whether the first charging current value exceeds a first reference value in order to detect an overcurrent. The at least one processor may identify whether the second charging current value exceeds a second reference value in order to detect an overcurrent.

According to an embodiment, when the first charging current value exceeds the first reference value, the at least one processor may obtain a signal (e.g., interrupt) notifying identification of the first charging current value exceeding the first reference value from the interface power management integrated circuit (IF PMIC). The at least one processor may set a total charging current in response to obtaining the signal notifying that the first charging current value exceeds the first reference value.

According to an embodiment, when the second charging current value exceeds the second reference value, the at least one processor may obtain a signal (e.g., interrupt) notifying identification of the second charging current value exceeding the second reference value from the direct current integrated circuit (DC IC). The at least one processor may set a total charging current in response to obtaining the signal notifying that the second charging current value exceeds the second reference value. Meanwhile, according to an embodiment, the at least one processor may obtain the signal notifying the identification of the second charging current value from the IF PMIC. The DC IC may transfer the second charging current value to the IF PMIC through I2C. Thereafter, the IF PMIC may identify whether the second charging current value exceeds the second reference value. The IF PMIC may transmit the signal notifying the identification of the second charging current value to the at least one processor.

According to an embodiment, the first reference value may be determined based on the guaranteed current of the first battery. According to an embodiment, the second reference value may be determined based on the guaranteed current of the second battery. For example, when a current exceeding the guaranteed current value of the first battery flows through the first battery, the at least one processor may regulate the total charging current to lower the first charging current value. For example, when a current exceeding the guaranteed current value of the second battery flows through the second battery, the at least one processor may regulate the total charging current to lower the second charging current value.

The at least one processor may perform operation 305 when the first charging current value exceeds the first reference value, or the second charging current value exceeds the second reference value (YES in operation 303). The at least one processor may perform operation 307 when the first charging current value is less than or equal to the first reference value and the second charging current value is less than or equal to a second reference value.

In operation 305, the at least one processor may set the total charging current to a second value. According to embodiments, the at least one processor may set the total charging current to the second value lower than the first value in order to decrease the first charging current value, when the first charging current value is higher than the first reference value. When the second charging current value is higher than the second reference value, the at least one processor may set the total charging current to the second value lower than the setting value of the total charging current in order to decrease the second charging current value. According to an embodiment, the second value may be a value obtained by subtracting a designated value from the setting value of the total charging current. For example, the second value may be a value obtained by subtracting 50 millimeter ampere (mA) from the setting value of the total charging current. For example, the second value may be a value obtained by subtracting 100 mA from the setting value of the total charging current. According to an embodiment, the second value may be a value obtained by subtracting a value based on a difference between the first charging current value and the first reference value from the setting value of the total charging current. The second value may be a value obtained by subtracting a value based on a difference between the second charging current value and the second reference value from the setting value of the total charging current. For example, when the first charging current value is higher than the first reference value by 30 mA, the second value may be a value obtained by subtracting 60 mA from the setting value of the total charging current. For example, when the second charging current value is higher than the second reference value by 30 mA, the second value may be a value obtained by subtracting 60 mA from the setting value of the total charging current.

In operation 307, the at least one processor may perform a stabilization operation for the first charging current value and the second charging current value. The charging efficiency of the first battery may be higher as the first charging current value is closer to the first guaranteed current value of the first battery. The at least one processor may perform a stabilization operation for the first charging current value to converge to a value within a range adjacent to the first guaranteed current value of the first battery. The charging efficiency of the second battery may be higher as the second charging current value is closer to the second guaranteed current value of the second battery. The at least one processor may perform a stabilization operation for the second charging current value to converge to a value within a range adjacent to the second guaranteed current value of the second battery. Hereinafter, the operations of the electronic device for stabilizing the charging current value are described in greater detail below with reference to FIG. 4.

FIG. 4 is a flowchart illustrating an example operation of an electronic device for stabilizing a first charging current value and a second charging current value according to various embodiments. In FIG. 4, description is made of the operations of at least one processor for stabilizing the first charging current value and the second charging current value. Such a stabilization of the charging current value may refer, for example, to an operation to converge to the guaranteed current of the battery. The operations of the electronic device (e.g., the electronic device 101 of FIG. 1) may be performed by at least one processor (e.g., the processor 120 of FIG. 1, the AP 201 of FIG. 2A, or a processor in IF PMIC 203 of FIG. 2A) or an IC controlled by the at least one processor (e.g., IF PMIC 203 of FIG. 2A or DC IC 205 of FIG. 2A).

Referring to FIG. 4, in operation 401, the at least one processor may identify whether the first charging current value is less than a third reference value and the second charging current value is less than a fourth reference value. The at least one processor may perform operation 405 when the first charging current value is less than the third reference value and the second charging current value is less than the fourth reference value (YES in operation 401). The at least one processor may perform operation 403 when the first charging current value is greater than or equal to the third reference value or the second charging current value is greater than or equal to the fourth reference value (NO in operation 401). According to embodiments, the third reference value may be lower than the first reference value. The fourth reference value may be lower than the second reference value. According to an embodiment, the third reference value may be a value obtained by subtracting a designated value from the first reference value. For example, the third reference value may be a value obtained by subtracting 50 mA from the first reference value. For example, the third reference value may be a value obtained by subtracting 100 mA from the first reference value. According to an embodiment, the fourth reference value may be a value obtained by subtracting a designated value from the second reference value. For example, the fourth reference value may be a value obtained by subtracting 50 mA from the second reference value. For example, the fourth reference value may be a value obtained by subtracting 100 mA from the second reference value.

In operation 403, the at least one processor may monitor the first charging current value and the second charging current value. According to an embodiment, the at least one processor may perform operations for controlling the charging current of FIG. 3 (e.g., the operations 301 to 307 of FIG. 3).

In operation 405, the at least one processor may identify whether the measured value of the total charging current is less than or equal to an initial setting value (e.g., the first value of the total charging current in the operation 301 of FIG. 3). The at least one processor may perform operation 407 when the measured value of the total charging current is less than or equal to the initial setting value (YES in operation 405). The at least one processor may perform the operation 403 when the measured value of the total charging current exceeds the initial setting value (NO in operation 405). According to various embodiments, the at least one processor may not increase the total charging current in case where the measured value of the total charging current is equal to or greater than the first value set as the full charging current, and thus, the first charging current value and the second charging current value can be monitored without a separate re-setting. This is because the first value is determined based on the guaranteed current of the first battery and the guaranteed current of the second battery.

In operation 407, the at least one processor may set the total charging current to a third value. According to an embodiment, this is because when the measured value of the total charging current is less than the setting value of the total charging current, the at least one processor may regard it as the total charging current being set low. Thus, the at least one processor may set the total charging current to the third value higher than the setting value of the total charging current. According to an embodiment, the third value may be a value obtained by adding a designated value to a setting value of the total charging current. For example, the third value may be a value obtained by adding 50 mA to the setting value of the total charging current. For example, the third value may be a value obtained by adding 100 mA to the setting value of the total charging current. The at least one processor may re-set the total charging current to a third value in order to set the total charging current higher, which was set excessively low to prevent and/or reduce overcurrent.

FIG. 5 is a flowchart illustrating an example operation of an electronic device for indicating an abnormal state of a path between a battery and a resistor according to various embodiments. Operations of the electronic device (e.g., the electronic device 101 of FIG. 1) may be performed by at least one processor (e.g., the processor 120 of FIG. 1, the AP 201 of FIG. 2A, or a processor in the IF PMIC 203 of FIG. 2A).

Referring to FIG. 5, in operation 501, at least one processor may set the total charging current to a second value. The at least one processor may set the total charging current to the second value, based on a procedure of overcurrent determination using a passive device (e.g., the operation 303 of FIG. 3). The at least one processor may set the total charging current value to the second value lower than a current setting value in order to prevent and/or reduce occurrence of overcurrent in the first battery and the second battery. The current setting value may be an initial setting value (e.g., the first value of operation 301 of FIG. 3) or a value previously re-set through a charging current control (e.g., charging current control of FIG. 3 or charging current control of FIG. 4).

In operation 503, the at least one processor may identify whether a difference value obtained by subtracting the second value from the initial setting value (e.g., the first value of operation 301 of FIG. 3) exceeds a threshold value. The difference value may indicate how much the current setting has changed from the initial setting according to the charging current control in operation 501. In order to detect an abnormal state, the processor may identify whether the difference value exceeds the threshold value. For example, the threshold value may be 300 mA. As another example, the threshold value may be 500 mA. The at least one processor may perform operation 505 when the difference value exceeds the threshold value (YES in operation 503). The at least one processor may perform operation 507 when the difference value is less than or equal to the threshold value (NO in operation 503).

In operation 505, a notification indicating an abnormal state of a power path for the first battery or a power path for the second battery may be displayed on the display. The difference between the first value and the second value may indicate a changed size of a setting value of the total charging current. The at least one processor may identify that an abnormal state has occurred if the changed size of the setting value of the total charging current exceeds the threshold value. When the first charging current value for the first battery continues to exceed the first reference value, even though the setting value of the total charging current is lowered to the second value, then the electronic device may identify that the power path for the first battery is in an abnormal state. Similarly, if the second charging current value for the second battery continues to exceed the second reference value even though the total charging current is lowered to the second value, then the electronic device may identify that the power path for the second battery is in an abnormal state. For example, when a short circuit occurs between the first power path and the second path toward the second battery, overcurrent may occur.

According to an embodiment, the at least one processor may determine that an abnormal state is detected based on the difference between the first value and the second value. The at least one processor may display an alarm notifying an abnormal condition of the route on a display.

In operation 505, it is described that a notification for indicating an abnormal state of the power path is provided to a user by means of a visual method, but the present disclosure is not limited thereto. According to an embodiment, such a notification for indicating an abnormal state of the power path may be provided to a user in any way such as e.g., a visual, tactile, and/or auditory manner. For example, the notification may be delivered to the user by a notification message from a wireless earphone connected to the electronic device (e.g., the electronic device 101 of FIG. 1). For example, the notification may be delivered to the user by means of a notification message and/or vibration of a smart watch connected to the electronic device (e.g., the electronic device 101 of FIG. 1). For example, the notification may be also provided to the user through a notification message of smart glasses operatively coupled with the electronic device (e.g., the electronic device 101 of FIG. 1).

In operation 507, the at least one processor may monitor the first charging current value and the second charging current value. According to an embodiment, the at least one processor may perform operations for controlling the charging current of FIG. 3 (e.g., the operations 301 to 307 of FIG. 3). According to an embodiment, the at least one processor may perform operations for stabilizing the charging current of FIG. 4 (e.g., the operations 401 to 407 of FIG. 4). The at least one processor may increase defect detection capability in a power charging path of an electronic device, using a method according to an embodiment.

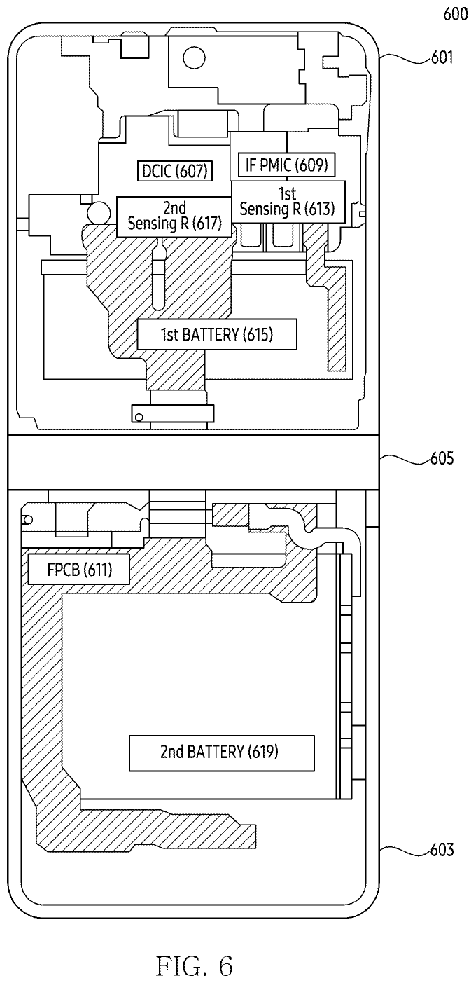

FIG. 6 is a diagram illustrating an example of an electronic device according to various embodiments.

Referring to FIG. 6, it is shown by way of an example a cross-sectional view 600 of the electronic device according to an embodiment. A first housing 601 may be connected to a second housing 603 via a hinge structure 605. The electronic device (e.g., the electronic device 101 of FIG. 1) may be a foldable electronic device, including the first housing 601 and the second housing 603 connected to each other by means of the hinge structure 605, but the disclosure is not limited thereto. The electronic device may be an electronic device having various form factors. For example, the electronic device may be a rollable electronic device in which the second housing slides relative to the first housing. A direct current integrated circuit (DC IC) 607 (e.g., the DC IC 205 of FIG. 2A) and an interface power management integrated circuit (IF PMIC) 609 (e.g., the IF PMIC 203 of FIG. 2A) may be connected through I2C (Inter Integrated Circuit). A first sensing resistor 613 (e.g., the first sensing resistor 207 of FIG. 2A) may be connected to the IF PMIC 609 through a flexible printed circuit board (FPCB) 611. The first sense resistor 613 may be connected to a first battery 615 (e.g., the first battery 209 of FIG. 2A) through the FPCB 611. A second sensing resistor 617 (e.g., the second sensing resistor 211 of FIG. 2A) may be connected to the DC IC 607 through the FPCB 611. The second sensing resistor 617 may be connected to a second battery 619 (e.g., the second battery 213 of FIG. 2A) through the FPCB 611. The FPCB 611 may refer to a flexible printed circuit board.

According to an embodiment, the foldable electronic device 101 may have various operating states. For example, the electronic device 101 may provide a folded state through the hinge structure 605. In the folded state, one surface of the first housing 601 and one surface of the second housing 603 may be disposed to face each other. For example, an unfolded state may be provided through the hinge structure 605 of the electronic device 101. In the unfolded state, one surface of the first housing 601 and one surface of the second housing 603 may be arranged to form an angle with a designated range (e.g., greater than 0 degrees and no more than 180 degrees).

According to an embodiment, the foldable electronic device may include a first battery 615 in a first housing 601. The first battery 615 may be disposed in a region area of the first housing 601. The foldable electronic device may include the DC IC 607 and the IF PMIC 609 in the first housing 601. The foldable electronic device may include the first sensing resistor 613 and the second sensing resistor 617 in the first housing 601. The first sensing resistor 613 may be disposed in the region of the first housing 601. The second sensing resistor 617 may be disposed in the region of the first housing 601. The foldable electronic device may include a second battery 619 in the second housing 603. The second battery 619 may be disposed in a region of the second housing 603.

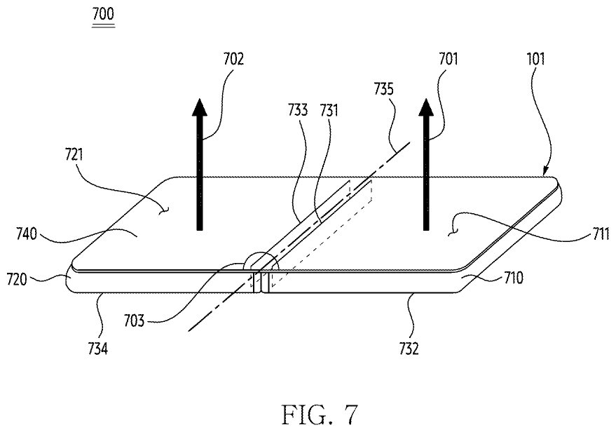

FIG. 7 is a perspective view illustrating an example of an unfolded state of an electronic device according to various embodiments.

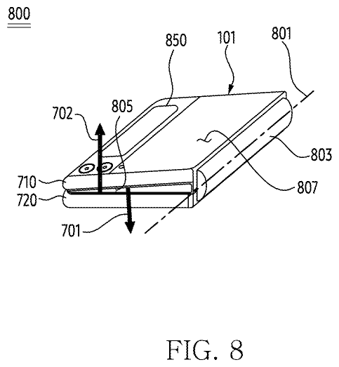

FIG. 8 is a perspective view illustrating an example of a folded state of an electronic device according to various embodiments.

According to an embodiment, the electronic device 101, which is a foldable electronic device, may provide various operating states through the first display 740. For example, the electronic device 101 may provide either one of an unfolded state and a folded state.

Referring to FIG. 7, the electronic device 101 may be provided with an unfolded state 700 in which a first housing 710 and a second housing 720 are fully stretched out with respect to each other by means of a hinge structure included in a folding housing (e.g., a folding housing 803 shown in FIG. 8).

According to an embodiment, the first housing 710 may include a first surface 711, a third surface facing and spaced apart from the first surface 711 (e.g., a third surface 807 shown in FIG. 8), and a first side surface 731 and a second side surface 732 positioned between the first surface 711 and the third surface 807.

According to an embodiment, the second housing 720 may include a second surface 721, a fourth surface (not shown) facing and separated from the second surface 721, and a third side surface 733 and a fourth side surface 734 positioned between the second surface 721 and the fourth surface.

According to an embodiment, the folding housing may include a hinge structure rotatably connecting the first side 731 of the first housing 710 and the third side 733 of the second housing 720 facing the first side surface 731, with respect to a folding axis 735.

According to an embodiment, the state 700 may refer to a state that a first direction 701 toward which the first surface 711 of the first housing 710 faces corresponds to a second direction 702 toward which the second surface 721 of the second housing 720 faces. For example, in the state 700, the first direction 701 may be substantially parallel to the second direction 702. For example, in the state 700, the first direction 701 may be substantially the same as the second direction 702.

According to an embodiment, in the state 700, the first surface 711 and the second surface 721 may form a substantially flat surface. For example, an angle 703 between the first face 711 and the second face 721 in the state 700 may be substantially 180 degrees. For example, the state 700 may refer to a state in which the entire display area of the first display 740 may be substantially provided on one plane. According to an embodiment, in the state 700, the display area of the first display 740 may not include any curved surface. The unfolded state may be referred to as an outspread state or an outspreading state.

Referring to FIG. 8, the electronic device 101 may be in a folded state 800 in which the first housing 710 and the second housing 720 are fully folded-in by means of a hinge structure in the folding housing 803.

According to an embodiment, the folded state 800 may refer to a state that the first direction 701 toward which the first surface 711 (not shown in FIG. 8) faces is different from the second direction 702 toward which the second surface 721 (not shown in FIG. 8) faces. For example, in the state 800, the angle between the first direction 701 and the second direction 702 may be of substantially 180 degrees, so that the first direction 701 and the second direction 702 face away from each other. For example, in the state 800, the angle 805 between the first surface 711 and the second surface 721 may be substantially zero degree. The folded state may be also referred to as a folding state. For example, in the electronic device 101, the first display 711 and the second surface 721 face each other by means of the hinge structure in the folding housing 803, thereby providing the state 800 in which the display area of the first display 740 corresponding to the first surface 711 substantially fully overlaps the display area of the first display 740 corresponding to the second surface 721. For example, the electronic device 101 may provide the state 800 in which the first direction 701 is substantially opposite to the second direction 702. As another example, the state 800 may refer, for example, to a state in which the display area of the first display 740 is hidden from the user's field of view looking at the electronic device 101. However, the present disclosure is not limited thereto.

According to an embodiment, the first display 740 may be bent by rotation provided through a hinge structure in the folding housing 803. For example, in the state 800, a portion of the display area of the first display 740 may be bent. For example, the portion of the display area of the first display 740 may be in a curved state to prevent and/or reduce breakage of the first display 740 in the folding state. However, the present disclosure is not limited thereto.

For example, the processor 120 may identify the angle between the first direction 701 to which the first surface 711 of the first housing 710 faces and the second direction 702 to which the second surface 721 of the second housing 720 faces, through at least one of a Hall sensor in the electronic device 101, a first sensor in the electronic device 101, a rotation sensor in the folding housing 803, or a stretch in the electronic device 101.

Meanwhile, according to an embodiment, the first housing 710 may include a second display 850 on a third surface 807 facing away from the first surface 711. For example, the second display 850 may be used to provide visual information in the folded state in which the display area of the first display 740 is not visible.

According to an embodiment, the electronic device 101 may include at least one antenna arranged in at least a portion of the second side surface 732 of the first housing 710. The electronic device 101 may include at least one antenna arranged in at least a portion of the fourth side surface 734 of the second housing 720. For example, the at least one antenna formed in at least a portion of the second side 732 of the first housing 710 may include a first antenna. The at least one antenna formed in at least a portion of the fourth side 734 of the second housing 720 may include a second antenna.

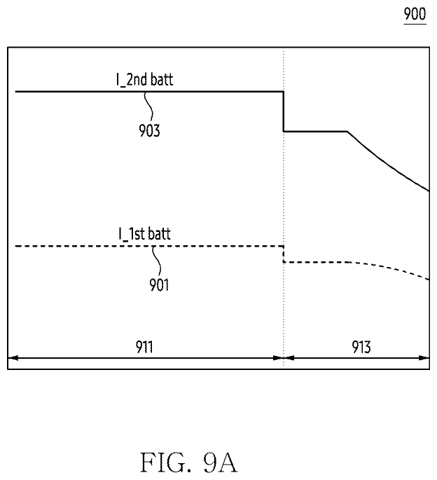

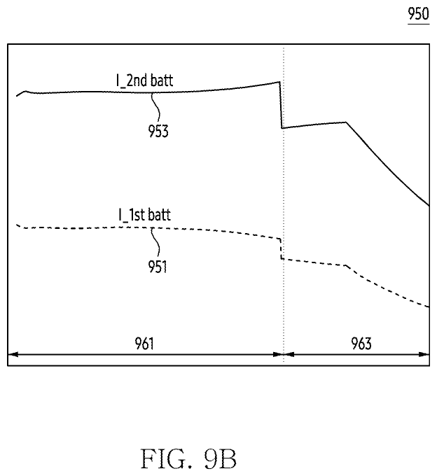

FIG. 9A is a graph illustrating performance of charging current control of an electronic device using a limiter according to an various embodiments.

Referring to FIG. 9A, a graph 900 may represent current intensity for each battery, when controlling current using a limiter IC, wherein y-axis of the graph 900 may represent current intensity, and x-axis of the graph 900 may represent time. A dotted line 901 may indicate the current intensity of the first battery over time. A solid line 903 may indicate the current intensity of the second battery over time.

The graph 900 may represent the change in current intensity by the current control using a limiter IC. In a first region 911 of the graph 900 is indicated the change in current intensity before execution of the current control operation. Further, in a second region 913 of the graph 900 is indicated the change in current intensity after execution of the current control operation. In the second region 913, the charging of the first battery can be carried out within a certain limit that does not go beyond a designated limit of a first limiter IC of the first battery. Further, in the second region 913, the charging of the second battery may be carried out within a certain limit that does not go beyond a designated limit of the second limiter IC of the second battery. At this time, the more each battery gets charged, the less current will flow therethrough.

FIG. 9B is a graph illustrating performance of charging current control of an electronic device using a passive element according to various embodiments. Active devices such as limiter ICs dissipate more power. FIG. 9B shows that as the current is measured based on the passive element, a battery usage time may increase.

Referring to FIG. 9B, a graph 950 may represent the current intensity for each battery without any limiter IC (e.g., in case of a passive device being used). The y-axis of the graph 950 indicates the current intensity, and the x-axis of the graph 950 represents time. A dotted line 951 indicates the current intensity of the first battery over time. A solid line 953 indicates the current intensity of the second battery over time.

The graph 950 may show a result of controlling the charging current according to an embodiment. The charging current control may include operations in FIGS. 3 and 4. Here, a first reference value may be a guaranteed current value of the first battery, and a second reference value may be a guaranteed current value of the second battery. A second value may be a value obtained by subtracting 50 mA from the first value. A third reference value may be a value obtained by subtracting 50 mA from the first reference value. A fourth reference value may be a value obtained by subtracting 50 mA from the second reference value.

In the first region 961, a ratio of a current intensity (e.g., dotted line 951) of the first battery to a current intensity (e.g., solid line 953) of the second battery may correspond to a ratio of a capacity of the first battery to a capacity of the second battery. The at least one processor may set the first value based on the capacity of the first battery and the second battery. In the second region 963, the first battery may be charged within the limit of the first guaranteed current of the first battery. Further, in the second region 963, the second battery may be charged within the limit of the second guaranteed current of the second battery. The more each battery being charged, the less current may flow therethrough. The current may be controlled only by means of the current control based on the sensing resistance according to an embodiment. For example, the at least one processor can control the current using the method according to the embodiments.

As described above, an example electronic device may comprise: at least one processor, a first battery, a second battery, a first sensing integrated circuit (IC) configured to identify a measurement value of a total charging current for the first battery and the second battery through a first sensing resistor electrically connected to the first battery and the second battery, and a second sensing IC configured to identify a second charging current value for the second battery through a second sensing resistor electrically connected to the second battery. The at least one processor is configured to: set the total charging current for charging the first battery and the second battery to a first value, and set the total charging current to a second value less than the first value, based on identifying a first charging current value greater than a first reference value or the second charging current value greater than a second reference value. The first charging current value is identified based on the measurement value of the total charging current and the second charging current value.

According to an example embodiment, the at least one processor is further configured to set the total charging current to a third value greater than the first value, based on the first charging current value being less than a third reference value or the second charging current value being less than a fourth reference value.

According to an example embodiment, the first sensing IC may include an interface power management integrated circuit (IF PMIC) configured to charge the first battery and the second battery.

According to an example embodiment, the at least one processor is further configured to display on a display a notification for indicating an abnormal state of a power path for the first battery or a power path for the second battery based on the second value, a difference between the second value and the first value being greater than a threshold value.

According to an example embodiment, the at least one processor is further configured to obtain, from the first sensing IC, a signal notifying that the first charging current value is greater than the first reference value.

According to an example embodiment, the at least one processor is further configured to obtain, from the second sensing IC, a signal indicating the identification of the second charging current value being greater than the second reference value.

According to an example embodiment, the at least one processor is further configured to identify a third charging current value measured through a third sensing resistor connected to a third battery. The at least one processor is further configured to set the total charging current to the second value based on a third charging current value, the second value being less than the first value, the third charging current value being greater than a fifth reference value.

According to an example embodiment, the first sensing resistor includes a passive device disposed between the first battery and the first sensing IC, without an integrated circuit (IC) for limiting current. The second sensing resistor includes a passive device disposed between the second battery and the second sensing IC, without an IC for limiting current.

Operations of the electronic device may be performed by at least one processor (e.g., a processor 120 of FIG. 1, AP 201 of FIG. 2A, or a processor in IF PMIC 203 of FIG. 2A) of the electronic device or by an IC controlled by the at least one processor (e.g., IF PMIC 203 of FIG. 2A or DC IC 205 of FIG. 2A). Hereinafter, at least one processor may include an AP 201 of FIG. 2A, a processor in the IF PMIC of FIG. 2A, or a processor in the DC IC of FIG. 2A. In the following, for example, at least some of the methods may be performed by the AP 201 of FIG. 2A. For example, at least some of the methods may be performed by the processor in the IF PMIC 203 of FIG. 2A. For example, at least some of the methods may be performed by the processor within the DC IC 205 of FIG. 2A.

As described above, according to an example embodiment, a method performed by an electronic device comprises: setting a total charging current for charging a first battery and a second battery to a first value; identifying a measurement value of the total charging current through a first sensing resistor electrically connected to the first battery and the second battery; identifying a second charging current value for the second battery through the second sensing resistor electrically connected the second battery; and setting the total charging current to a second value less than the first value, based on identifying a first charging current value being greater than a first reference value or the second charging current value being greater than a second reference value; wherein first charging current value may be identified based on the measurement value of the total charging current and the second charging current value.

According to an example embodiment, the method further comprises setting the total charging current to a third value greater than the first value based on the first charging current value or the second charging current value, the first charging current value being less than a third reference value, and the second charging current value being less than a fourth reference value.

According to an example embodiment, the measurement value of the total charging current may be identified through an interface power management integrated circuit (IF PMIC). The measurement value of the second charging current may be identified through a direct current (DC) IC.

According to an example embodiment, the method further comprises displaying on a display a notification indicating an abnormal state of a power path for the first battery or a power path for the second battery based on the second value, a difference between the second value and the first value being greater than a threshold value.

According to an example embodiment, the method further comprises obtaining, from the first sensing IC, a signal notifying that the first charging current value is greater than the first reference value.

According to an example embodiment, the method further comprises obtaining, from the second sensing IC, a signal indicating the identification of the second charging current value greater than the second reference value.

According to an example embodiment, the method further comprises identifying a third charging current value measured via a third sensing resistor connected to a third battery. The method further comprises setting the total charging current to a second value based on the third charging current value, the second value being less than the first value, and the third charging current value being greater than a fifth reference value.

According to an example embodiment, the first sensing resistor includes a passive device disposed between the first battery and the first sensing IC, without an integrated circuit (IC) for limiting current. The second sensing resistor includes a passive device disposed between the second battery and the second sensing IC, without an IC for limiting current.

As described above, according to an example embodiment, an electronic device comprises: a first battery, a second battery, an interface power management integrated circuit (IF PMIC) configured to charge the first battery and the second battery, a direct current integrated circuit (DC IC), a first sensing resistor connected to the IF PMIC, a second sensing resistor connected to the DC IC, and at least one processor configured to control the IF PMIC and the DC IC. The first sensing resistor may be disposed between the IF PMIC and the first battery. The second sensing resistor may be disposed between the first sensing resistor and the second battery.

According to an example embodiment, the IF PMIC and the DC IC may be connected through an inter integrated circuit (I2C).

According to an example embodiment, the electronic device further includes a third battery. The electronic device further includes a third sensing resistor disposed between the first sensing resistor and the third battery.

According to an example embodiment, the first battery may be connected to the first sensing resistor through a first flexible printed circuit board (FPCB), and the second battery may be connected to the second sensing resistor through a second FPCB.

The electronic device according to various embodiments disclosed herein may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may be interchangeably used with other terms, for example, “logic,” “logic block,” “part,” or “circuitry”. A module may be a single integral component, or a minimum unit or part thereof, adapted to perform one or more functions. For example, according to an embodiment of the disclosure, the module may be implemented in a form of an application-specific integrated circuit (ASIC).

Various embodiments as set forth herein may be implemented as software (e.g., a program 140) including one or more instructions that are stored in a storage medium (e.g., an internal memory 136 or an external memory 138) that is readable by a machine (e.g., an electronic device 101). For example, a processor (e.g., a processor 120 of an electronic device 101) of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., a compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device, comprising:
at least one processor;
a first battery;
a second battery;
a first sensing integrated circuit (IC) configured to identify a measurement value of a total charging current for the first battery and the second battery through a first sensing resistor electrically connected to the first battery and the second battery; and
a second sensing IC configured to identify a second charging current value for the second battery through a second sensing resistor electrically connected to the second battery,
wherein the at least one processor is configured to:
set the total charging current for charging the first battery and the second battery to a first value,
set the total charging current to a second value less than the first value, based on identifying a first charging current value greater than a first reference value or the second charging current value greater than a second reference value, and
wherein the first charging current value is identified based on the measurement value of the total charging current and the second charging current value.

2. The electronic device of claim 1, wherein the at least one processor is further configured to set the total charging current to a third value greater than the first value, based on the first charging current value being less than a third reference value or the second charging current value being less than a fourth reference value.

3. The electronic device of claim 1,
wherein the first sensing IC includes an interface power management integrated circuit (IF PMIC) configured to charge the first battery and the second battery, and
wherein the second sensing IC includes a direct current integrated circuit (DC IC).

4. The electronic device of claim 1,
wherein the at least one processor is further configured to display on a display a notification indicating an abnormal state of a power path for the first battery or a power path for the second battery based on the second value, and
wherein a difference between the second value and the first value is greater than a threshold value.

5. The electronic device of claim 1, wherein the at least one processor is further configured to obtain, from the first sensing IC, a signal notifying that the first charging current value is greater than the first reference value.

6. The electronic device of claim 1, wherein the at least one processor is further configured to obtain, from the second sensing IC, a signal indicating identification of the second charging current value being greater than the second reference value.

7. The electronic device of claim 1, wherein the at least one processor is further configured to:
identify a third charging current value measured through a third sensing resistor connected to a third battery,
set the total charging current to the second value based on a third charging current value, the second value being less than the first value, and
wherein the third charging current value is greater than a fifth reference value.

8. The electronic device of claim 1, wherein the first sensing resistor includes a passive device disposed between the first battery and the first sensing IC, without an integrated circuit (IC) configured to limit current, and
wherein the second sensing resistor includes a passive device disposed between the second battery and the second sensing IC, without an IC configured to limit current.

9. A method performed by an electronic device, the method comprising:
setting a total charging current for charging a first battery and a second battery to a first value;
identifying a measurement value of the total charging current through a first sensing resistor electrically connected to the first battery and the second battery;
identifying a second charging current value for the second battery through the second sensing resistor electrically connected the second battery; and
setting the total charging current to a second value less than the first value, based on identifying a first charging current value being greater than a first reference value or the second charging current value being greater than a second reference value,
wherein the first charging current value is identified based on the measurement value of the total charging current and the second charging current value.

10. The method of claim 9, further comprising setting the total charging current to a third value greater than the first value based on the first charging current value or the second charging current value,
wherein the first charging current value is less than a third reference value, and
wherein the second charging current value is less than a fourth reference value.

11. The method of claim 9,
wherein the measurement value of the total charging current is identified through an interface power management integrated circuit (IF PMIC); and
wherein the second charging current value is identified through a direct current integrated circuit (DC IC).

12. The method of claim 9, further comprising displaying on a display a notification for indicating an abnormal state of a power path for the first battery or a power path for the second battery based on the second value,
wherein a difference between the second value and the first value is greater than a threshold value.

13. The method of claim 9, further comprising obtaining, from a first sensing integrated circuit (IC) connected to the first sensing resistor, a signal notifying that the first charging current value is greater than the first reference value.

14. The method of claim 9, further comprising obtaining, from a second sensing integrated circuit (IC) connected to the second sensing resistor, a signal indicating the identification of the second charging current value greater than the second reference value.

15. The method of claim 9, further comprising:
identifying a third charging current value measured via a third sensing resistor connected to a third battery,
setting the total charging current to a second value based on the third charging current value, the second value being less than the first value, and
wherein the third charging current value is greater than a fifth reference value.

16. The method of claim 9, wherein the first sensing resistor includes a passive device disposed between the first battery and a first sensing integrated circuit (IC), without an IC configured to limit current, and
wherein the second sensing resistor includes a passive device disposed between the second battery and a second sensing IC, without an IC configured to limit current.

17. An electronic device comprising:
a first battery;
a second battery;
an interface power management integrated circuit (IF PMIC) configured to charge the first battery and the second battery;
a direct current integrated circuit (DC IC);
a first sensing resistor connected to the IF PMIC;
a second sensing resistor connected to the DC IC;
at least one processor configured to control the IF PMIC and the DC IC;
wherein the first sensing resistor is disposed between the IF PMIC and the first battery, and
wherein the second sensing resistor is disposed between the first sensing resistor and the second battery.

18. The electronic device of claim 17, wherein the IF PMIC and the DC IC are connected through an inter integrated circuit (I2C).

19. The electronic device of claim 17, further comprising:
a third battery; and
a third sensing resistor disposed between the first sensing resistor and the third battery.

20. The electronic device of claim 17,
wherein the first battery is connected to the first sensing resistor through a first flexible printed circuit board (FPCB),
wherein the second battery is connected to the second sensing resistor through a second FPCB.
